(19) United States
(12) Patent Application Publication
(10) Pub. No.: US 2005/0028059 A1
(43) Pub. Date: Feb. 3, 2005

(54) Processor interface for test access port

(76) Inventors: Jean-Francois Cote, Chelsea (CA); Benoit Nadeau-Dostie, Gatineau (CA)

Correspondence Address: LOGICVISION (CANADA), INC., 1565 CARLING AVENUE, SUITE 508, OTTAWA, ON, K1Z 8R1, CA

(21) Appl. No.: 10/892,203

(22) Filed: Jul. 16, 2004

Related U.S. Application Data
(60) Provisional application No. 60/491,558, filed on Aug. 1, 2003.

(51) Int. Cl. G01R 31/28

(52) U.S. Cl. 714/724

(57) ABSTRACT

A processor interface for test access port comprises a write buffer for storing data output by a processor and having a command field, a data field, and a serial output connected to a serial input of the test access port, a read buffer for storing data output by the test access port for access by the processor and having a data field, and a serial input connected to a serial output of the test access port; and a control circuit responsive to a command stored in the command field for generating test access port control signals for transferring test data from the write buffer to the test register and from the test register to the read buffer via test access port serial input and serial output.

### CROSS-REFERENCE TO RELATED APPLICATIONS

This application claims the benefit of U.S. Provisional Patent Application Ser. No. 60/491,558 filed Aug. 4, 2003.

### BACKGROUND OF THE INVENTION

1. Field of the Invention

The present invention generally relates to the testing of semiconductor circuits and systems, and, more specifically, to a processor interface for a test access port and to a method that provides access to test functions controlled by a standard test access port.

2. Description of Related Art

The test access port specified by the IEEE1149.1 standard is often used to provide access to all test functions of an integrated circuit. The test access port has a serial input (TDI), a serial output (TDO), a clock (TCK), a test mode select (TMS) and an optional reset (TRST). The standard test access port includes an instruction register and controls test data registers which implement various test functions. Test data registers can be simple scan chains, or can be part of complex embedded test or self-test controllers to provide setup or diagnostic functions. The test access port includes a state machine shown in FIG. 3. Test data to be applied through the test access port can be documented with the Serial Vector Format (SVF) used in the industry.

The aforementioned inputs and output, which form the standard test access port interface, are usually connected directly to the integrated circuit pins as prescribed by the standard. However, the circuit pins are sometimes not available in the electronic system hosting the integrated circuit. The pins might not be connected to the package so that direct access to the test access port is only available during wafer sort. In some instances, the pins are connected to the package but are accessible only during board manufacturing using a tester. In still other instances, the circuit pins are in use to implement a system function and cannot be used to access test functions. Whatever the reason might be, there is a need for a way of accessing test functions when the standard test access port interface is not directly accessible.

Processors are used routinely in electronic systems and are likely candidates to interface to a standard test access port to access test functions. Processors can be embedded on the same integrated circuit as the standard test access port or located elsewhere in the system. Unfortunately, processor inputs and outputs are not directly compatible with those of a standard test access port. A first significant difference is that some processors use parallel data communication to transfer data rather than serial communication required by the standard test access port, while processors that use serial data communication employ a different protocol from that of the standard test access port.

Various attempts have been made to overcome the above described problems. Hergott U.S. Pat. No. 6,567,325 issued on May 20, 2003 for “Apparatus and Method for System Access to Tap Controlled BIST of Random Access Memory ” discloses a method of interfacing a test controller with a processor where the test controller is also controllable from a test access port. However, the interface is specific to the type of test controller disclosed and only allows operation of self-test controllers in their GO/NOGO mode of operation. Test controllers often require more diagnostic modes of operation that require scanning registers that are internal to the test controller and which is better accomplished by accessing the test controller through the test access port.

Cromer et al. U.S. Pat. No. 6,263,373 issued on Jul. 17, 2001 for “Data Processing System and Method for Remotely Controlling Execution of a Processor Utilizing a Test Access Port” discloses a special purpose processor which determines one of a plurality of test access port commands associated with one of a plurality of debug commands and causes a processor to execute one of a plurality of processor actions. A server computer system remotely debugs the execution of the processor utilizing a built-in test access port. Cromer et al. overcomes the drawback concerning the type-specific interface of Hergott because the test controller is accessed through the test access port instead of bypassing it, potentially providing access to the full functionality of the test controller(s) connected it. However, Cromer et al. neither explain how the test access port is connected to accept commands (or test data in general) from both the circuit pins and the special purpose processor, nor how the test data is translated from a format compatible for network transmission and understandable by the special purpose processor to a format that is compatible with the test access port and vice-versa.

Josephson et al. U.S. Pat. No. 6,484,275 issued on Nov. 19, 2002 for “System and Method for Interfacing Data with a Test Access Port of a Processor” do disclose a method by which a test access port can be connected to interface circuit pins and a processor. Josephson et al. provides a processor which includes a special memory that stores test data and test access port control data. The processor includes a test application that transmits the test data and the test access port control data from the memory to the test access port of the processor. The test access port then utilizes the test data and the control data to capture state data that defines a state of the processor while the processor is executing. The test access port is interfaced with a multiplexer which is also interfaced with the memory and an input interface capable of receiving external signals. Based on a control signal, the multiplexer selects signals defined by the test and control data transmitted from the memory or selects external signals transmitted from an input interface. The multiplexer then transmits the selected signals to the test access port, which captures state data based on the selected signals.

Josephson et al. suffers from a number of drawbacks. First, the control signal that selects between circuits pins and the processor is not itself connected to a circuit pin which makes it impossible to guarantee compliance with the IEEE1149.1 standard. Second, Josephson et al. do not explain how to synchronize the transfer of multiple test data packets with the state machine of the test access port. Third, Josephson et al. require explicitly providing a memory for storing the test mode select signal (TMS) which might be expensive.

It will be seen that there is a need for an interface that will convert data and control signals from a processor to signals that can be connected to a standard test access port. The interface should be able to accommodate as many types of processors as possible by using commonly available signals, a variable data bus width and a simple protocol. It should be possible to select between a processor interface and a direct interface through circuit pins in a manner that is compliant with the IEEE1149.1 standard. It should be easy to convert test data, formatted to be applied through the direct interface, so that it can be applied through the processor interface.

### SUMMARY OF THE INVENTION

The present invention seeks to provide an interface for use between a process and a test access port and a method that overcome the above described drawbacks of the prior art.

One aspect of the present invention is generally defined as a test access port interface for transferring test data between a selected test register connected to a test access port having a state machine responsive to test access port control input signals and a processor. The interface comprises a write buffer for storing data output by the processor, the write buffer having a command field, a data field, and a serial output connected to a serial input of the test access port; a read buffer for storing data output by the test access port for access by the processor, the read buffer having a data field, and a serial input connected to a serial output of the test access port; and a control circuit responsive to a command stored in the command field for generating test access port control signals for transferring test data from the write buffer to the test register and from the test register to the read buffer via test access port serial input and serial output.

Another aspect of the present invention is generally defined as a method for transferring test data between a test register connected to a test access port having a state machine responsive to test access port control input signals and a processor. The method comprises (a) loading processor output data into a write buffer having a command field and a data field, the processor output data including data loaded into the data field and command data loaded into the command field and identifying a final state in which to position the test access port state machine upon completion of data communication with the test register; (b) generating and applying test access port control signals to test access port control inputs to serially transfer write buffer data field contents to the test register via the test access port serial input and concurrently serially transfer test register serial output data into a data field of a read buffer via the test access port serial output; (c) waiting for the transfer to complete; and (d) reading the read buffer to retrieve test data transferred from the test register.

### BRIEF DESCRIPTION OF THE DRAWINGS

These and other features of the invention will become more apparent from the following description in which reference is made to the appended drawings in which:

FIG. 1 illustrates a circuit having Test Access Port (TAP) controller, a processor and a dual interface according to an embodiment to the present invention;

FIG. 2 illustrates a processor interface according to an embodiment to the present invention; and

FIG. 3 illustrates a state diagram for a standard TAP controller state machine.

### DETAILED DESCRIPTION OF PREFERRED EMBODIMENTS

In the following detailed description, numerous specific details are set forth in order to provide a thorough understanding of the present invention. However, it will be understood by those skilled in the art that the present invention may be practiced without these specific details. In other instances, well known methods, procedures, components and circuits have not been described in detail so as not to obscure aspects of the present invention.

In general, the present invention provides a dual test access port interface that provides access to test data registers which implement test functions under control of a standard test access port. A direct interface connects the inputs and output of the standard test access port to circuit pins. A processor interface can be selected to drive the inputs and receive the output of the standard test access port. By default, the control signal selecting between the processor interface and the direct interface selects the processor interface. During manufacturing, this default value of the control signal can be overridden to select the direct interface to make the circuit compliant to the IEEE1149.1 standard.

The processor interface has a write buffer, a read buffer and a control circuit in the form of a finite state machine (FSM). The write buffer contains a command field and a data field. The read buffer contains a status field and a data field. The processor interface has a write mode and a read mode. In write mode, the write buffer is loaded by a processor and causes the FSM to control the serial transfer of the write data to the test access port's instruction register or to a test data register. Preferably, commands in the write buffer indicate the final state of the of the standard test access port. A command can also cause the test access port to be reset. During the serial transfer of the write buffer data, read data output by a selected test register is loaded into and stored in the read buffer. The status field indicates the availability of read data in the read buffer. In read mode, the contents of the read buffer is read by the processor.

Test registers (instruction register or test data register) are accessed by configuring the processor interface in write and read mode for a number of times equal to the width of the currently selected test register divided by the width of the write and read buffer data field. Appropriate padding of data is performed when the width of the test register is not an integer multiple of the write and read buffer data field width. Test data available for the direct interface is easily translated for the processor interface.

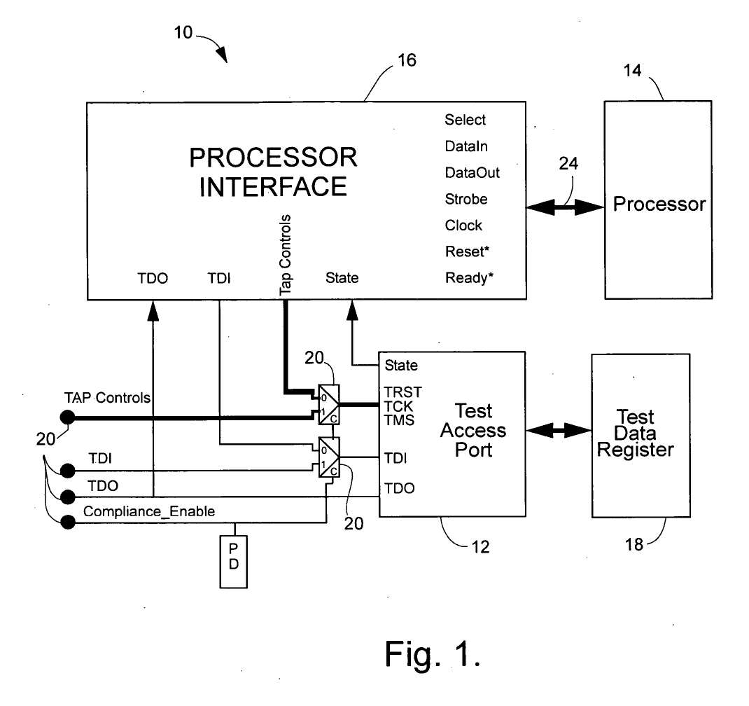

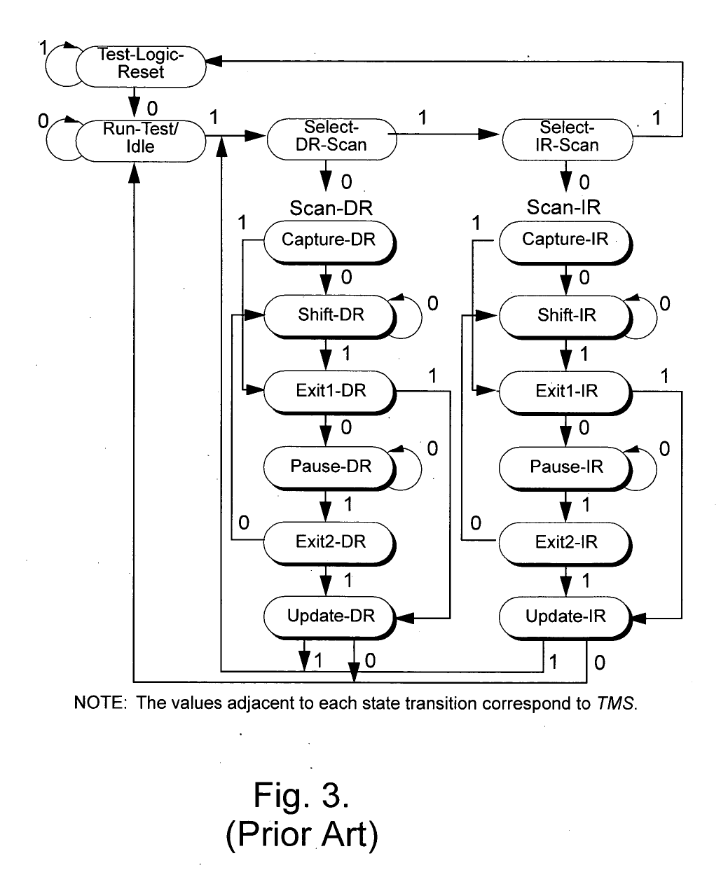

FIG. 1 illustrates a circuit 10 having a test access port 12, a processor 14 and a processor interface 16 according to an embodiment of the present invention. The test access port has control inputs TRST, TCK and TMS, a serial input, TDI, and a serial output, TDO. The test access port has a state machine (not shown) and an instruction register (not shown) as documented in the IEEE1149.1 standard. The state diagram of the state machine is shown in FIG. 3 for reference. The state of the state machine is available at an output, State, of the test access port. The test access port is connected to test data registers 18 which implement test or debug functions.

Selectors 20 are provided to configure the circuit in a “direct interface” mode or in a “processor interface” mode. The direct interface mode connects the inputs, both control and serial, and the serial output of the standard test access port to circuit pins 22. The processor interface connects the test access port inputs and output to the processor interface. Selectors 20 are controlled by a control signal, Compliance_Enable, applied to a circuit pin, to select between the processor interface mode (Logic 0) and the direct interface mode (Logic 1). The processor interface is selected by default. This default selection facilitates access of test functions in the system. During manufacturing, the default value of the control signal can be overridden to select the direct interface and make the circuit compliant to the IEEE1149.1 standard which requires such direct interface.

The processor interface is connected to processor 14. The processor can be embedded in circuit 10 or located in another circuit in the system. The processor generates various input signals Select, Strobe, Clock and DataIn which are applied to the processor interface. The processor interface generates and applies a data output, DataOut, signal to the processor. All signals are readily available from processor bus 24 which can access a large number of registers, each having a respective address. The processor interface is mapped to one such address. When the address corresponding to the processor interface is decoded (decoding logic not shown), the Select signal is asserted to indicate that the processor will perform a write or a read operation at this address. The Strobe signal is asserted when a write operation is performed. The data to be written into the processor interface is applied at DataIn. When the Strobe signal is not asserted, indicating a read operation, the processor interface outputs data at DataOut. In many systems with a processor, the DataIn and DataOut signals are combined in a bidirectional bus.

The clock used for the processor interface is also used for the test access port. This clock can be synchronous or asynchronous to the processor clock. An optional reset signal (Reset) can be applied to the processor interface to reset it and the test access port. Another optional signal (Ready) can be generated to indicate that a command has been completed and that the processor interface is ready to accept other commands. This signal can be used to interrupt the processor.

As explained in more detail below, the present invention provides a method for transferring test data between a test register connected to a test access port having a state machine responsive to test access port control input signals and a processor. The method comprises (a) loading processor output data into a write buffer having a command field and a data field, the processor output data including data loaded into the data field and command data loaded into the command field and identifying a final state in which to position the test access port state machine upon completion of data communication with the test register; (b) generating and applying test access port control signals to test access port control inputs to serially transfer write buffer data field contents to the test register via the test access port serial input and concurrently serially transfer test register serial output data into a data field of a read buffer via the test access port serial output; (c) waiting for the transfer to complete; and (d) reading the read buffer to retrieve test data transferred from the test register.

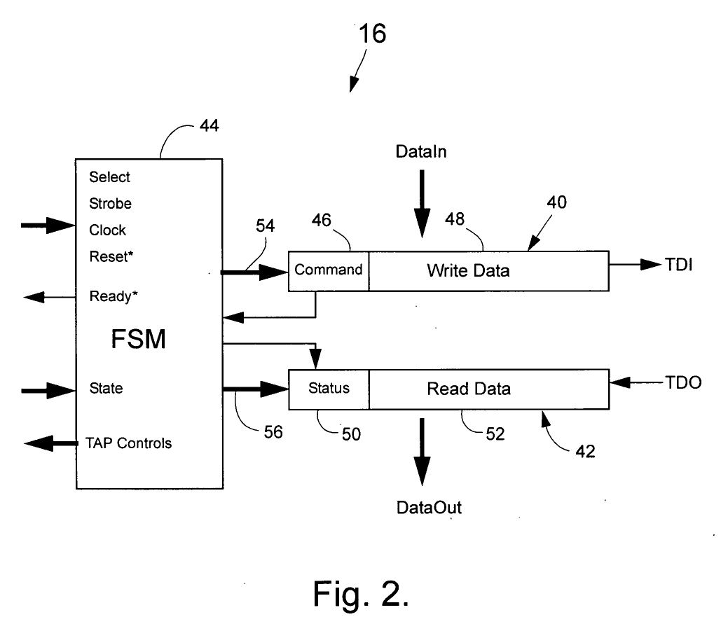

The processor interface is shown in more detail in FIG. 2. The interface has a write buffer 40, a read buffer 42 and a control circuit in the form of a finite state machine (FSM) 44. Write buffer 40 contains a command field 46 and a data field 48. Read buffer 42 contains a status field 50 and a data field 52. The write and read buffers are comprised of a plurality of memory elements controlled by control signals output by FSM 44 at 54 and 56. The width of the command field 46 plus that of data field 48 is chosen to be compatible with the width of the processor data bus. The width of the processor data bus is not necessarily the same as the width of the test registers which need to be accessed. Accordingly, as explained more fully later, the FSM is adapted to accommodate this by responding to predetermined commands which identify the destination test register and perform appropriate sequences of write and read operations.

The processor interface has a write mode and a read mode (Select is active and Strobe is inactive). In write mode, the write buffer is loaded with input data at DataIn coming from the processor. FSM 44 decodes the command field and takes appropriate action. For example, some commands will cause the serial transfer of the write data to the test access port instruction register or to a test data register. For these commands, the final state of the standard test access port can be specified. A command can also cause the test access port to be reset. In this case, the write data is ignored. An example of a command set is given below for a command field of two bits. Other commands could be added if desired.

TABLE 1

| Code | Command |
|---|---|
| 00 | Scan N bits of test access port instruction register and go to |
| | Pause_IR state |
| 01 | Scan N bits of test data register and go to Pause_DR state |
| 10 | Scan N bits of currently selected register and go to Run_Test_Idle |
| 11 | Go to Test_Logic_Reset |

Read data is stored in the read buffer during the serial transfer of write buffer data (first three commands above). The status field indicates the availability of read data in the read buffer. In read mode, the contents of the read buffer is read by the processor. The status field can contain information equivalent to the Ready signal described above. The processor can poll the read buffer, i.e., read data from the read data from the read buffer, until the status field indicates that the data is valid and ready to be read. This method of accessing the read buffer to determine if the processor interface is ready can be used as an alternative to interrupting the processor.

The width of test registers may vary from one another and from the width of the write and read buffers. Accordingly, test registers (instruction register or test data register) are accessed by configuring the processor interface in write and read mode for a number of times equal to the width of the destination test register currently selected divided by the width of the write and read data fields. Appropriate padding of data when the width of the test register is not an integer multiple of the write and read data fields. This is illustrated in the example below.

The Serial Vector Format (SVF) is a language that describes the serial operations performed on a test access port which conforms to the IEEE1149.1 standard. For example, the following statement:
SIR 19 TDI (7FFFD) TDO (7FFFD) MASK (00033) indicates that 19 bits need to be scanned in and out through TDI and TDO, respectively, to load the instruction register of the test access port. The numbers in parentheses indicate that actual test data to be sent through TDI or received from TDO. All data is in hexadecimal format, i.e., each symbol corresponds to four binary bits of data. The MASK component is optional and indicates the TDO bits that need to be compared. By default, all bits are compared.

By way of example, suppose that the processor bus data width is 16 bits. This means that the write and read data field buffer width is:

N=width of processor bus−width of command field=16−2=14 since two bits of each buffer are used as command and status bits. Two write operations, each followed by a read operation, are needed to shift in an instruction and shift out the result of the capture operation of the test access port instruction register. The operations are as follows:

| | | |
|---|---|---|
| 1) | Write 3A00 | scan N bits then go to Pause_IR. Add 9 padding 0s on |
| | | TDI LSBs |
| 2) | Read BFFD | |
| 3) | Write AFFF | scan N bits then go to Run_Test_Idle |
| 4) | Read 801F | add 9 padding 0s on TDO MSBs and MASK. |

The first operation to the write buffer involves configuring the processor interface into write mode and applying 3A00 at the DataIn input. The two most significant bits are the command field, “00” in this case. This command indicates that N (14) bits of test data will be transferred in and out the test access port and that state of the test access port, after execution of this command, should be Pause_IR. The remaining 14 bits constitute the write data field. Since the total number of test data bits transferred must be a multiple of 14, some padding needs to be done. For TDI, the padding is implemented by adding least significant bits (LSBs) to the original test data. In this case, the write data field is loaded with the five LSBs of the original test data (“11101”) padded with nine additional bits with a value of 0. The value of the padding bits is arbitrary.

The second operation involves configuring the processor interface into read mode which will output a value of BFFD on DataOut. The two most significant bits are the status field, “10” in this case. The “1” indicates that the data read is valid. The “0” bit has no significance in this case. The width of the status field was arbitrarily chosen to match the width of the command field to simplify implementation and potentially allow sharing the same hardware to implement the write buffer and the read buffer. The remaining 14 bits constitute the read data field. Here, no padding is necessary and the data is simply the 14 LSBs of the TDO signal.

The third operation involves configuring the processor interface into its write mode again. The command field bits are set to “10” this time which indicates that the state of the test access port after execution of this command should be Run_Test_Idle. The data put in the write data field simply corresponds to the 14 MSBs of the TDI signal.

The fourth operation involves configuring the processor interface into its read mode again. The two MSBs are again “10”. The read data field requires padding by adding MSBs to the original test data specified for TDO and MASK. Nine additional bits with a value of 0 have been added in this case. As mentioned before, the value used for the padding bits is arbitrary. However, the value used for the corresponding MASK bits must be “0” in order to suppress the comparison of these padding bits.

The present invention allows the transfer of test data between the processor and the test access port in an asynchronous fashion. That is, the clocks used for the processor interface arid the processor can be asynchronous and free-running. When transferring test data asynchronously, there are necessarily wait periods. In the embodiment shown, the stable states of the standard state machine are used to wait between the write operations of the processor that will initiate a serial transfer of test data to the test access port. Another solution is to gate the clock applied to the test access port between transfers. In the particular case where the clock of the processor interface and that of the processor are synchronous, it is possible for the processor to count the number of clock cycles needed for the transfer and predict when the next operation (write or read) can take place without having to continuously read the status field of the read buffer or to wait for an interrupt of the Ready signal.

The present invention is applicable to all standards requiring the implementation of a test access port using a state machine designed according to the IEEE1149.1 standard. Such standards include, but are not limited to, IEEE1149.4, IEEE1149.6, IEEE1532. Other standards based on serial communication of test data can also be handled by the present invention.

Although the present invention has been described in detail with regard to preferred embodiments and drawings of the invention, it will be apparent to those skilled in the art that various adaptions, modifications and alterations may be accomplished without departing from the spirit and scope of the present invention. Accordingly, it is to be understood that the accompanying drawings as set forth hereinabove are not intended to limit the breadth of the present invention, which should be inferred only from the following claims and their appropriately construed legal equivalents.

1. A test access port interface for transferring test data between a selected test register connected to a test access port having a state machine responsive to test access port control input signals and a processor, said interface comprising:
a write buffer for storing data output by said processor, said write buffer having a command field, a data field, and a serial output connected to a serial input of said test access port;
a read buffer for storing data output by said test access port for access by said processor, said read buffer having a data field, and a serial input connected to a serial output of said test access port; and
a control circuit responsive to a command stored in said command field for generating test access port control signals for transferring test data from said write buffer to said test register and from said test register to said read buffer via test access port serial input and serial output.

2. An interface as defined in claim 1, further including selector means responsive to a control signal for selecting between a direct interface in which said test access port is connected to circuit pins and a processor interface in which said test access port is connected to said interface.

3. An interface as defined in claim 2, said control signal being applied from a circuit pin.

4. An interface as defined in claim 3, said control signal having a default value when said circuit pin is not driven.

5. An interface as defined in claim 3, said default value being derived from a pullup or a pulldown.

6. An interface as defined in claim 4, said default value selecting said processor interface.

7. An interface as defined in claim 1, said command field identifying a test access port state machine final state following serial data communication with a test register, and, said control circuit responding to command data in said command field upon receipt of new test data written into said write buffer by said processor.

8. An interface as defined in claim 7, said command field further identifying a test register type to be accessed.

9. An interface as defined in claim 8, said test register type including one of a test access port instruction register and a data register.

10. An interface as defined in claim 1, said control circuit being operable to apply a sequence of test access port control signals to said test access port to serially transfer write data to a selected test register and leave said test access port in a stable state upon completion of said transfer.

11. An interface as defined in claim 10, said test access port control inputs being defined by the IEEE1149.1 standard and including a test mode select (TMS) signal and a clock signal, and said stable state including Pause_DR, Pause_IR, Run_Test_Idle and Test_Logic_Reset.

12. An interface as defined in claim 10, wherein, said control circuit being operable to load an invalid data code into said status field prior to serial transfer of write buffer data to indicate that read buffer data is not valid and load a valid data code into said status field after serially transferring test data from a selected test register to said read buffer data field concurrently with the serial transfer of write data, and update said status field upon completion of said transfer to indicate that the read data is valid.

13. An interface as defined in claim 10, said processor interface having a clock input for a clock used to control said processor interface and said test access port.

14. An interface as defined in claim 10, said control circuit generating a ready output, derived from said status field of said read buffer, indicating whether said processor interface is in the process of performing a serial transfer of test data.

15. An interface as defined in claim 10, said processor interface having a reset input for use in resetting said processor interface and said test access port.

16. An interface as defined in claim 1, said processor interface having an address corresponding to an address of a processor address bus, and said processor interface having a select input which is set to an active value when said processor is to perform a write or read operation to or from said processor interface.

17. An interface as defined in claim 1, said processor interface having a data input coupled to said processor and a strobe input for a strobe signal output by said processor, said strobe signal being set to an active value and data input being written into said write buffer when said processor performs a write operation to said processor interface.

18. A interface defined in claim 17, said processor interface having a data output, said data output being connected to said read buffer when said select signal is active and said strobe signal is inactive.

19. A method for transferring test data between a test register connected to a test access port having a state machine responsive to test access port control input signals and a processor, said method comprising:
(a) loading processor output data into a write buffer having a command field and a data field, the processor output data including data loaded into said data field and command data loaded into said command field and identifying a final state in which to position said test access port state machine upon completion of data communication with said test register;
(b) generating and applying test access port control signals to test access port control inputs to serially transfer write buffer data field contents to said test register via the test access port serial input and concurrently serially transfer test register serial output data into a data field of a read buffer via the test access port serial output;
(c) waiting until said transfer is complete; and
(d) reading said read buffer to retrieve test data transferred from said test register.

20. A method as defined in claim 19, further including, when said test register is wider than said write buffer:
(e) repeating steps (a) to (d) until access of the test register is complete.

21. A method as defined in claim 19, said command further includes identifying a test register type and said generating and applying including selecting said test register type prior to said transfer.

22. A method as defined in claim 21, said test register type including one of a test access port instruction register and a data register.

23. A method as defined in claim 19, said test access port control signals include a test mode select (TMS) control signal and a clock signal.

24. A method as defined in claim 19, further including, prior to step (b), loading a status code into a read buffer status field to indicate that the data contained in the read buffer data field is invalid and, following step (b), loading a status code into said status field to indicate that the data contained in the read buffer data field is valid.

25. A method as defined in claim 19, said generating and applying including applying control signals to said test access port to position said test access port in said final state following each serial transfer.

26. A method as defined in claim 19, further including, padding original test data when the width of a selected test register divided by the width of said write buffer data field is not an integer.

27. A method as defined in claim 26, said padding including adding dummy least significant bits to the write buffer data field data and adding most significant bits to the read buffer data field data such that the width of the data to be transferred between the selected register and the buffers divided by the width of the write buffer data field is an integer.

28. A method as defined in claim 19, said waiting includes counting a predetermined number of clock cycles required to perform the transfer.

29. A method as defined in claim 19, said waiting includes interrupting the processor when a ready signal is detected.

30. A method as defined in claim 19, said waiting includes polling said status field until a code corresponding to valid read status code is present.

31. A method as defined in claim 19, further including omitting step (d) when read data is not required.

32. A method as defined in claim 19, wherein test data is derived from test data used by a direct interface to circuit pins.

33. A method as defined in claim 32, wherein test data is documented using Serial Vector Format (SVF).

34. A method as defined in claim 19, further including concurrently with said generating and applying test access port control signals, generating and applying write and read buffer memory element control signals and selected test register memory element control signals.
